(19) United States
(12) Patent Application Publication
(10) Pub. No.: US 2022/0248568 A1
(43) Pub. Date: Aug. 4, 2022

(54) HASHBOX FOR IMMERSION COOLING

(71) Applicant: Scott Douglas Bennett, Orondo, WA (US)

(72) Inventor: Scott Douglas Bennett, Orondo, WA (US)

(21) Appl. No.: 17/726,340

(22) Filed: Apr. 21, 2022

Related U.S. Application Data
(63) Continuation of application No. 17/341,679, filed on Jun. 8, 2021.
(60) Provisional application No. 63/076,862, filed on Sep. 10, 2020.

(51) Int. Cl. H05K 7/20; G05B 13/02; F28F 27/02

(52) U.S. Cl. CPC H05K 7/20281; F28F 27/02; G05B 13/024; H05K 7/20236

(57) ABSTRACT

Systems and methods may (i) determine, for a first device, a first setting associated with a first rate at which fluid is supplied to a first container in which the first device resides and (ii) determine, for a second device, a second setting associated with a second rate at which fluid is supplied to a second container in which the second device resides. The systems and methods may cause a first valve to adjust such that the first rate of fluid is supplied to the first container, and cause a second valve to adjust such that the second rate of fluid is supplied to the second container. The systems and methods may receive data associated with the first device and determine, for the first device and based on the data, a third setting associated with a third rate at which the fluid is supplied to the first container.

### CROSS-REFERENCE TO RELATED APPLICATIONS

This application is a continuation of and claims priority to U.S. patent application Ser. No. 17/341,679, filed Jun. 8, 2021, which claims priority to U.S. Provisional Patent Application No. 63/076,862, filed Sep. 10, 2020, entitled “Individualized Containers for Optimum Flow Control for Immersion Cooled Computers,” the entirety of which are herein incorporated by reference.

### BACKGROUND

Electronic computers, drivers, and storage devices, such as those found in data centers, generate large amounts of heat. In some instances, these devices may require cooling. For example, the devices may operate in air-conditioned rooms where fans dissipate heat. However, fan-based cooling requires large amounts of power and are often inefficient. Moreover, as computing and processing throughputs increase, conventional cooling techniques may fail to provide cooling needs. For example, as devices are manufactured with smaller components (e.g., microprocessor, circuits, etc.) that are capable of handling increased loads, larger amounts of heat are generated. To accommodate for this increase in heat, some devices are cooled by immersing the devices in liquid. However, with immersion cooling, devices are not cooled according to their optimal parameters. As a result, conventional techniques that employ immersion cooling are often inefficient.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features. The systems and devices depicted in the accompanying figures are not to scale and components within the figures may be depicted not to scale with each other.

FIG. 1 illustrates an example environment that includes a plurality of devices cooled using immersion cooling, according to an embodiment of the present disclosure. In some instances, valves may regulate the amount of fluid supplied to containers in which device(s) are at least partially disposed. A management system may monitor and oversee the operating parameters of the devices for use in adjusting the flow rate of fluid supplied to the containers.

FIG. 2 illustrates a communicative coupling between the management system and one or more components for monitoring the devices of FIG. 1, according to an embodiment of the present disclosure.

FIG. 3A illustrates a first perspective view of an example container configured to receive a device, according to an embodiment of the present disclosure.

FIG. 3B illustrates a second perspective view of the container of FIG. 3A, according to an embodiment of the present disclosure.

FIG. 4A illustrates an example device disposed within the container of FIG. 3A, according to an embodiment of the present disclosure.

FIG. 4B illustrates devices disposed within the containers of FIG. 3A, respectively, according to an embodiment of the present disclosure.

FIG. 5 illustrates an example process for determining a flow rate of fluid supplied to one or more devices in immersion cooling, according to an embodiment of the present disclosure.

FIG. 6 illustrates an example process for adjusting a flow rate of fluid supplied to one or more devices in immersion cooling, according to an embodiment of the present disclosure.

### DETAILED DESCRIPTION

Described herein are, among other things, systems and methods for adjusting a flow rate of fluid supplied to individual devices for immersion cooling. Generally, immersion cooling is a cooling technique in which devices (e.g., computer components, electronics, servers, etc.) are at least partially submerged in a thermally conductive dielectric liquid, coolant, or fluid. The fluid absorbs heat generated by the devices and, after being cooled, is reintroduced for further heat absorption. Given that the fluid has a higher specific heat capacity than air, immersion cooling allows for more efficient cooling of the devices.

Adjusting the flow rate of fluid to individual devices may optimally cool the devices and increase an operational performance of the devices. In some instances, an environment (e.g., building, facility, etc.) may include any number of devices that are placed within containers for immersion cooling. The containers are configured to receive the devices and are sized according to parameters of the devices (e.g., shape, size, etc.). A valve adjusts a rate at which the fluid is supplied into the container, and thus, adjusts the flow rate of fluid across the devices. Within the container the fluid absorbs heat from the device. The fluid then exists the container and may dissipate the absorbed heat via a heat exchanger (e.g., cooler, cooling tower, radiator, etc.). The fluid may then be conditioned before being reintroduced to the containers for further cooling.

In some instances, adjusting the flow rates may be based on a size of the devices, operating parameters of the devices, computational capacities of the devices, a size of the container, and so forth. For example, oftentimes devices are configured to operate at certain temperatures for optimizing a performance of the devices. In this sense, each of the devices may have a given or predetermined optimal operating temperature. In some instances, valves that supply fluid to the container may be adjusted such that the devices operate at their given operating temperature. As the devices handle increased computing loads, for example, the valves may be dynamically adjusted such that the device remains at the optimum operating temperature.

In some instances, each device may be placed within a respective container such that the flow rate to the respective containers may be individually controlled. This may, in some instances, increase an operational performance of the devices given that the devices are cooled according to their specific parameters. Moreover, cooling the devices on an individual level, as compared to placing a plurality of devices within a single container, may optimize a cooling efficiency. In other words, by adjusting a flow rate of fluid supplied to individual containers, the devices may be effectively cooled and fluid may be provided to other devices in need of cooling.

A management system may monitor, manage, and coordinate the flow rate of fluid within the environment. The management system may receive various information (e.g., data) for use in controlling the flow rate of fluid supplied to the containers. For example, the management system may receive temperatures of the fluid, both before entering the containers and after exiting the containers, temperatures of the devices, operating parameters of the devices (e.g., temperature, hashing power, wattage, etc.), and so forth. In such instances, the management system may communicatively couple to various sensor(s) (e.g., temperature sensors) and/or the devices themselves for receiving the information. The management system may be configured to store the information for use in adjusting the valves and in turn, the amount of fluid provided to the containers. In some instances, the management system may determine the flow rate of fluid provided to the containers knowing the setting of the valve (e.g., 25 percent open, 50 percent open, etc.), and/or the management system may communicatively couple to flow meters for determining the flow rate. The settings of the valve may correlate to, or be associated with, flow rates into the containers (e.g., 3.0 gallons per minute (GPM), 3.5 GPM, etc.). The valves may include solenoid valves or other electronically-controlled valves. The valves, themselves, may represent ball valves, butterfly valves, needle valves, gate valves, globe valves, and so forth.

To briefly illustrate, envision that a facility includes a plurality of devices, such as a first device, a second device, and a third device that all require cooling. The first device may be placed within a first container, the second device may be placed within a second container, and a third device may be placed within a third container. The containers for the first device, the second device, and the third device may be respectively sized. For example, it is envisioned that each device may have different footprints, shapes, etc. Thus, the first container, the second container, and the third container may be configured to receive the first device, the second device, and the third device, respectively. In such instances, the first device, the second device, and the third device may be submerged within the first container, the second container, and the third container, respectively.

The first container, the second container, and the third container are each fluidly connected to receive fluid. For example, the first container, the second container, and the third container may each include an inlet to receive the fluid. Moreover, the first container, the second container, and the third container, or supply lines fluidly coupled thereto, may include valve(s). The valve(s) control a flow rate of fluid supplied to the first container, the second container, and the third container. For example, a first valve may control a flow rate of fluid supplied to the first container, a second valve may control a flow rate of fluid supplied to the second container, and a third valve may control a flow rate of fluid supplied to the third container. In this instance, the first valve, the second valve, and the third valve may be respectively adjusted for controlling a flow rate of fluid into the first container, the second container, and the third container, respectively.

In some instances, and as noted above, the flow rate of fluid supplied to the first container, the second container, and the third container may be based on operating parameters of the devices within the first container, the second container, and the third container, respectively. For example, the first device within the first container may have a first optimal operating temperature (e.g., 80 degrees Fahrenheit), the second device within the second container may have a second optimal operating temperature (e.g., 85 degrees Fahrenheit), and the third device within the third container may have a third optimal operating temperature (e.g., 95 degrees Fahrenheit). As such, each of the valves may be adjusted for controlling the flow rate of fluid such that the devices are cooled to their respective optimal operating temperature, for example. Additionally, it is to be understood that the valves may be adjusted to modify the flow rate in instances where computing demands increase, an ambient temperature changes, and so forth.

In some instances, each of the optimal operating temperatures may be associated with respective hashing capacities, loads, or values of the devices. For example, each of the devices may be capable of performing a certain number of hashes per second (e.g., hashing power). To achieve the optimal number of hashes, the devices may require a certain operating temperature. That is, at a given temperature, the devices may be most efficient and capable of performing a maximum number of hashes. As such, by controlling the temperature of the devices, the devices may operate with optimal efficiency.

The containers may represent vessels, basins, tubs, and so forth that receive the devices. In some instances, the devices may be at least partially positioned within the containers, such the when fluid fills the container, the devices are at least partially submerged. However, a power receptacle and/or other ports (e.g., Ethernet, USB, etc.) may not be submerged once fluid is supplied to the container. To receive the fluid, each container may include a respective inlet fluidly connected to a valve and a feed line (e.g., supply line). In some instances, the inlet may be located proximate to a bottom of the container. An outlet, located proximate a top of the container, may permit the fluid to exit the container. In some instances, the top of the container may be opened such that the fluid may flow out the outlet (e.g., spillway). The fluid may be collected within a trough (e.g., basin) for conditioning and before being resupplied to the containers.

Although the above discussion is with regard to devices being placed within individual containers, in some instances, more than one device may be placed within a container. For example, like devices may be placed within a single container. Additionally, or alternatively, the devices may be grouped in certain containers based on operating parameters of the devices. For example, if two devices (whether similar or dissimilar) are configured to operate at a certain temperature, those two devices may be placed in the same container. In such instances, the devices may be in stacked relationship and the fluid may be configured to pass in between the devices for absorbing heat generated by the devices.

Thus, in light of the above, the present disclosure is directed to efficiently cooling devices using immersion cooling by adjusting a flow rate of fluid supplied to the containers in which the devices. With the systems and techniques disclosed herein, more devices may be located within a given environment, resulting in increased computational capacities. Such systems and techniques allow for significant gains in computer processing capabilities.

The present disclosure provides an overall understanding of the principles of the structure, function, device, and system disclosed herein. One or more examples of the present disclosure are illustrated in the accompanying drawings. Those of ordinary skill in the art will understand that the devices and/or the systems specifically described herein and illustrated in the accompanying drawings are non-limiting embodiments. The features illustrated or described in connection with one embodiment may be combined with the features of other embodiments. Such modifications and variations are intended to be included within the scope of the appended claims.

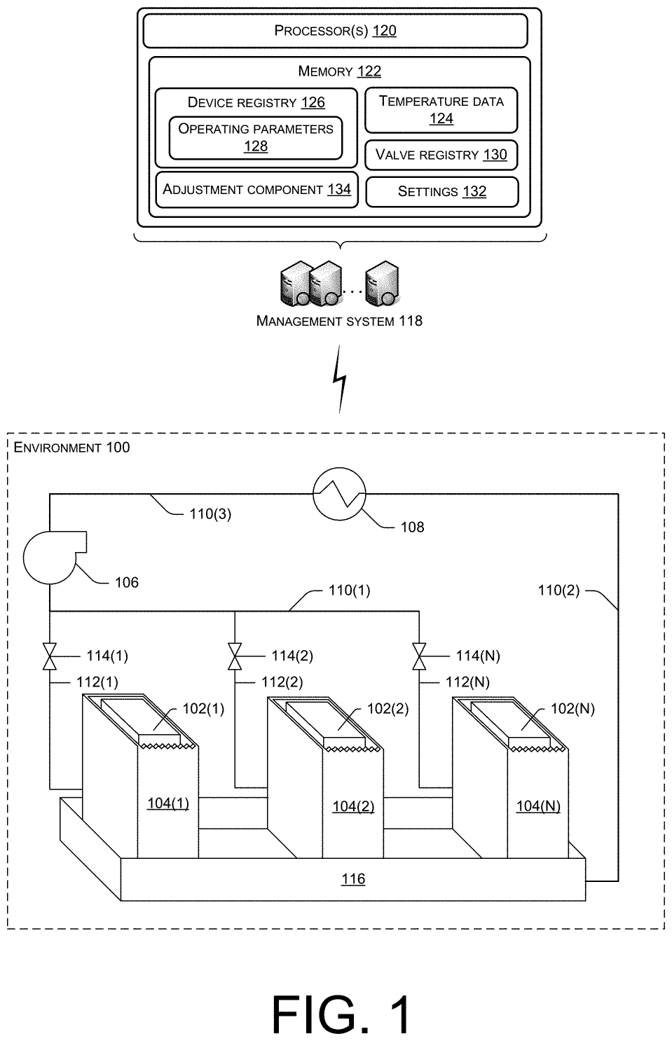

FIG. 1 illustrates an example environment 100 that includes a plurality of devices 102(1)-(N). In some instances, the environment 100 may be representative of a facility, data center, server facility, and the like in which the devices 102(1)-(N) are located. Generally, the devices 102(1)-(N) may be used for any computational purposes, such as, but not limited to telecommunications, data storage, data processing, data mining, data distribution, “on-demand computing,” offering “software as a service (SaaS),” “platform computing,” “network-accessible platform,” “cloud services,” “data centers,” etc. The devices 102(1)-(N), meanwhile, may include switches, storage systems, servers (e.g., virtual machine (VM) instances), processor(s), memory, routers, and the like. In some instances, the devices 102(1)-(N) may represent a computing infrastructure of processors, storage, software, data access, etc. that is maintained and accessible via a network such as the Internet. The devices 102(1)-(N) may include any number of processors, memory, and so forth.

As shown in FIG. 1, the devices 102(1)-(N) may include a first device 102(1), a second device 102(2), up to n^{th} devices 102(N). In some instances, the environment 100 may include containers 104(1)-(N) that receive the devices 102(1)-(N), respectively. For example, a first container 104(1) may receive the first device 102(1), a second container 104(2) may receive the second device 102(2), and an n^{th} container 104(N) may receive the n^{th} device 1020(N). The containers 104(1)-(N) may be sized, shaped, and/or otherwise configured to receive the devices 102(1)-(N). As shown, and as discussed in detail herein, the containers 104(1)-(N) may include a top, open, end into which the devices 102(1)-(N) are placed. Once placed within the containers 104(1)-(N), the devices 102(1)-(N) may be at least partially disposed within the containers 104(1)-(N) (e.g., within sidewalls of the containers 104(1)-(N)).

The environment 100 includes components for cooling the devices 102(1)-(N) using immersion cooling. For example, and in some instances, the environment 100 may include one or more pump(s) 106 (e.g., positive-displacement, centrifugal, axial-flow pumps, etc.), one or more heat exchanger(s) 108, lines 110(1)-(3) (e.g., conduit, piping, such as polyvinyl chloride (PVC) piping, hoses, etc.), feed lines 112, (1)-(N), valves 114(1)-(N), sensor(s), and so forth. The components may effectuate to supply coolant, dielectric liquid, or other fluid to the containers 104(1)-(N) for cooling the devices 102(1)-(N). For example, the pump 106 is shown fluidly connected to a first line 110(1). The first line 110(1) may branch or otherwise divide out to supply fluid to the containers 104(1)-(N). That is, as shown, a first feed line 112(1) may fluidly connect to the first line 110(1), a second feed line 112(2) may fluidly connected to the first line 110(1), and an n^{th} feed line 112(N) may fluidly connect to the first line 110(1). The first feed line 112(1) is shown being fluidly connected to the first container 104(1), the second feed line 112(2) is shown being fluidly connected to the second container 104(2), and the n^{th} feed line is shown being fluidly connected to the n^{th} container 104(N). As such, the first feed line 112(1) may supply fluid to the first container 104(1), the second feed line 112(2) may supply fluid to the second container 104(2), and the n^{th} feed line 112(N) may supply fluid to the n^{th} container 104(N).

A first valve 114(1) is disposed along the first feed line 112(1) for adjusting a flow rate of the fluid supplied to the first container 104(1). Likewise, a second valve 114(2) is disposed along the second feed line 112(2) for adjusting a flow rate of the fluid supplied to the second container 104(2), and an n^{th} valve 114(N) is disposed along the n^{th} feed line 112(1) for adjusting a flow rate of the fluid supplied to the n^{th} container 104(N). Depending on the cooling needs of the devices 102(1)-(N), the valves 114(1)-(N) may be respectively. dynamically adjusted to supply respective amounts of the fluid to the containers 104(1)-(N) for cooling the devices 102(1)-(N). As discussed herein, the valves 114(1)-(N) may be electronically controlled. For example, the valves 114(1)-(N) may include solenoid valves or other electronically-controlled valves. The valves 114(1)-(N), themselves, may represent ball valves, butterfly valves, needle valves, gate valves, globe valves, and so forth.

The containers 104(1)-(N) are shown being positioned in a trough 116 that collects fluid exiting the containers 104(1)-(N). For example, after the fluid enters the containers 104(1)-(N), the fluid may spill over the top of the containers 104(1)-(N) for collection within the trough 116. The containers 104(1)-(N) may include features for controlling the exiting of the fluid in a controlled manner. For example, a side of the containers 104(1)-(N) may include serrations such that the fluid exits the containers 104(1)-(N) at that side. Fluid collected in the trough 116 may pass through the heat exchanger 108 for cooling. That is, after the fluid absorbs heat (via the devices 102(1)-(N)), the fluid may pass through the heat exchanger 108 for conditioning the fluid. A second line 110(2) is shown fluidly connecting the through 116 to the heat exchanger 108. In some instances, the heat exchanger 108 may include a counter-current flow heat exchanger, a cross-flow heat exchanger, a spiral flow heat exchanger, a cooling tower, and the like. The heat exchanger 108 transfers thermal energy from the fluid to another medium (e.g., air or another fluid) for the purpose of cooling. After being collected, the fluid may recirculate within the environment 100. For example, the pump 106 is shown being fluidly connected to the heat exchanger 108 via a third line 110(3). The heat exchanger 108 may be located external to the environment 100 (or facility) in which the devices 102(1)-(N) reside. In some instances, one or more pumps may be fluidly connected to the lines 110(1)-(3) or additional lines for circulating the fluid. For example, a pump may be disposed between the trough 116 and the heat exchanger 108.

Although the environment 100 is shown including certain components, the environment 100 may include additional or alternative components. By way of example, the environment 100 may include additional throughs for collecting fluid from other containers. In some instances, the environment 100 may include separate systems for cooling respective devices. For example, a first system (e.g., pumps, heat exchanger, lines, etc.) may cool first devices, while another separate system may cool second devices. In such instances, any number of devices may be cooled within the environment 100 by any number of systems.

In some instances, the fluid may include a highly volatile dielectric liquid with a low boiling point relative to the temperature increase resulting from the heat generated by the devices 102(1)-(N). The dielectric liquid may not conduct electricity and/or may not react or interact with surrounding components when exposed to electricity or electrical components. This may increase a safety of the environment 100 and prevent shortages, shock, and so forth.

A management system 118 may communicatively couple to the devices 102(1)-(N), the pump(s) 106, and/or the valves 114(1)-(N) for use in determining whether to adjust a flow rate of fluid supplied to the containers 104(1)-(N) and/or to supply the containers 104(1)-(N) with respective flow rates of fluid. As shown, the management system 118 may include one or more processor(s) 120 and memory 122, which may store or otherwise have access to various modules, components, information, and/or database(s). As discussed herein, the management system 118 may continuously receive the information (e.g., data) from components within the environment 100 for use in determining whether to adjust a flow rate of the fluid.

The memory 122 is shown including, or having access to, temperature data 124, a device registry 126, operating parameters 128, a valve registry 130, and/or settings 132. The temperature data 124 may represent temperatures of the fluid throughout the lines 110(1)-(N), within or across the heat exchanger(s) 108, the devices 102(1)-(N), an air temperature within the environment 100, an ambient temperature external to the environment 100, and so forth. In some instances, the temperature data 124 may be received from sensor(s) located along the lines 110(1)-(N), from sensors disposed in the devices 102(1)-(N), from sensor(s) in the pump(s) 106, from sensor(s) in the trough 116, and so forth. In some instances, the temperature data 124 may be received according to a predetermined schedule (e.g., every second, every five seconds, etc.) and/or according to certain conditions (e.g., the devices 102(1)-(N) powering up, the devices 102(1)-(N) powering off, etc.).

The device registry 126 may represent a database of the devices 102(1)-(N) within the environment 100. The device registry 126 may store identifying information of the devices 102(1)-(N), such as type, manufacturer, processing power, and so forth. The device registry 126 may also store the operating parameters 128 associated with the devices 102(1)-(N). The operating parameters 128 may correspond to operational conditions, such as temperature, load, capacity, etc. at which the devices 102(1)-(N) are configured to operate. In some instances, the operating parameters 128 may include optimal operating parameters in which the devices 102(1)-(N) operate most efficiently. For example, the devices 102(1)-(N) may optimally operate a certain temperatures. At these temperatures, for example, the devices 102(1)-(N) may be configured to handle increased loads or perform an optimal number of hashes per second. Using the operating parameters 128, for example, as well as the temperature of the fluid, the management system 118 may adjust the flow rate of fluid supplied to the containers 104(1)-(N).

The valve registry 130 may contain information for communicating with the valves 114(1)-(N). For example, the valve registry 130 may indicate which valves 114(1)-(N) are fluidly connected to the containers 104(1)-(N). In this sense, the management system 118 may utilize the valve registry 130 for knowing which of the valves 114(1)-(N) to adjust for controlling the flow rate of fluid to a specific container.

The settings 132 may correspond to setting(s) of the pump(s) 106, the valves 114(1)-(N), the heat exchanger(s) 108, and so forth. For example, the settings 132 may include a speed of the pump(s) 106, an effectiveness of the heat exchanger 108, positions of the valves 114(1)-(N) (e.g., open, closed, half-open, etc.), flow rates, and so forth. In some instances, the pump(s) 106, the heat exchanger(s) 108, and/or the valves 114(1)-(N) may operate according to the settings 132 stored in the memory 122.

The memory 122 is further shown including an adjustment component 134. The adjustment component 134 may cause adjustments to the pump(s) 106, the valves 114(1)-(N), the heat exchanger(s) 108, and/or other components within the environment 100. For example, the adjustment component 134 may compare a temperature of the devices 102(1)-(N) against optimum temperatures stored in the operating parameters 128. If the temperature is different than the optimum temperature, or outside a certain threshold or range of temperatures, the adjustment component 134 may determine an adjustment to the valves 114(1)-(N). For example, the adjustment component 134 may cause the valves 114(1)-(N) to open to increase or decrease fluid flow to the containers 104(1)-(N) to either increase or decrease cooling, respectively. As noted above, the valves 114(1)-(N) may be selectively adjusted for modifying the rate of fluid supplied to the containers 104(1)-(N).

The adjustment component 134 may also be responsive to other conditions sensed within (or outside) of the environment 100. For example, as the heat exchanger 108 may dissipate heat to an ambient environment, the effectiveness of the heat exchanger 108 may vary depending on the time of day, time of year, and so forth. In such instances, the temperature of the fluid exiting the heat exchanger 108, and which is ultimately supplied to the containers 104(1)-(N), may vary. In such instances, the adjustment component 134 may throttle the valves 114(1)-(N) to either increase or decrease fluid flow. For example, if the temperature of the fluid exiting the heat exchanger 108 is greater than normal, or above a threshold amount, the adjustment component 134 may increase the flow rate across the valves 114(1)-(N) for supplying an increased amount of fluid to the containers 104(1)-(N). Conversely, if the temperature of the fluid exiting the heat exchanger 108 is less than normal, or less a threshold amount, the adjustment component 134 may decrease the flow rate across the valves 114(1)-(N) for supplying an decreased amount of fluid to the containers 104(1)-(N).

In some instances, the management system 118 may be located within the environment 100 or external to the environment 100. Although FIG. 1 illustrates each of the containers 104(1)-(N) containing one of the devices 102(1)-(N), in some instances, more than one device may be placed within a container. For example, devices 102(1)-(N) that have a similar operating temperature (e.g., optimum temperature) may be placed within a similar container. Additionally, although FIG. 1 illustrates that the valves 114(1)-(N) are coupled to the individual feed lines 112(1)-(N), in some instances multiple feed lines 112(1)-(N) may be fluidly connected to the same valve. For example, a single valve may control a flow rate of fluid supplied to multiple containers 104(1)-(N). Moreover, in some instances, valve(s) may be located upstream of the valves 114(1)-(N) for further controlling the fluid flow to the containers 104(1)-(N).

As used herein, a processor, such as the processor(s) 120 may include multiple processors and/or a processor having multiple cores. Further, the processor(s) may comprise one or more cores of different types. For example, the processor(s) may include application processor units, graphic processing units, and so forth. In one implementation, the processor(s) may comprise a microcontroller and/or a microprocessor. The processor(s) may include a graphics processing unit (GPU), a microprocessor, a digital signal processor or other processing units or components known in the art. Alternatively, or in addition, the functionally described herein can be performed, at least in part, by one or more hardware logic components. For example, and without limitation, illustrative types of hardware logic components that may be used include field-programmable gate arrays (FPGAs), application-specific integrated circuits (ASICs), application-specific standard products (ASSPs), system-on-a-chip systems (SOCs), complex programmable logic devices (CPLDs), etc. Additionally, each of the processor(s) may possess its own local memory, which also may store program components, program data, and/or one or more operating systems.

Memory, such as the memory 122 may include volatile and nonvolatile memory, removable and non-removable media implemented in any method or technology for storage of information, such as computer-readable instructions, data structures, program component, or other data. Such memory may include, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, RAID storage systems, or any other medium which can be used to store the desired information and which can be accessed by a computing device. The memory may be implemented as computer-readable storage media (“CRSM”), which may be any available physical media accessible by the processor(s) to execute instructions stored on the memory. In one basic implementation, CRSM may include random access memory (“RAM”) and Flash memory. In other implementations, CRSM may include, but is not limited to, read-only memory (“ROM”), electrically erasable programmable read-only memory (“EEPROM”), or any other tangible medium which can be used to store the desired information and which can be accessed by the processor(s).

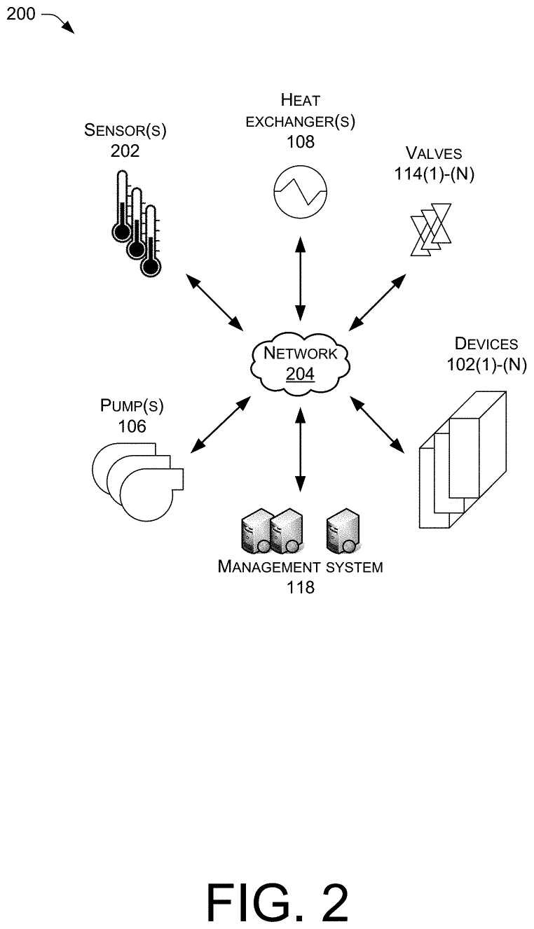

FIG. 2 illustrates an example system 200 adjusting the flow of fluid within the environment 100. In some instances, and as shown, the management system 118 may be in communication with the devices 102(1)-(N), the pump(s) 106, the heat exchanger(s) 108, the valves 114(1)-(N), and sensor(s) 202 via a network 204.

The communicative coupling between the devices 102(1)-(N), the pump(s) 106, the heat exchanger(s) 108, the valves 114(1)-(N), the management system 118, and the sensor(s) 202 permits the management system 118 to control an operation of the devices 102(1)-(N), the pump(s) 160, the heat exchanger(s) 108, the valves 114(1)-(N), and/or the sensor(s) 202, respectively. Additionally, the communicative coupling between the management system 118 and the devices 102(1)-(N), the pump(s) 106, the heat exchanger(s) 108, the valves 114(1)-(N), and/or the sensor(s) 202 allows the management system 118 to receive information associated with a performance of the devices 102(1)-(N), the pump(s) 106, the heat exchanger(s) 108, and/or the valves 114(1)-(N). For example, the management system 118 may receive data from the pump(s) 106 indicate a speed of the pump(s) 106, the management system 118 may receive data from the devices 102(1)-(N) indicating a temperature of the devices 102(1)-(N), and so forth.

The sensor(s) 202 may include temperature sensors, flow meter sensors, vibrational sensors, and so forth that indicate a performance of the system 200. In some instances, the sensor(s) 202 may be integrated within the devices 102(1)-(N), the pump(s) 106, the heat exchanger(s) 108, and/or the valves 114(1)-(N), or may be located external to the devices 102(1)-(N), the pump(s) 106, the heat exchanger(s) 108, and/or the valves 114(1)-(N). For example, the devices 102(1)-(N) may include thermometers that measure a temperature of the devices 102(1)-(N). Additionally, or alternatively, the sensor(s) 202 may measure a temperature of the fluid throughout the system 200 (e.g., within the containers 104(1)-(N), within the lines 110(1)-(N), etc.).

The network 204 may represent any type of communication network, including a data network, and may be implemented using wired infrastructure (e.g., cable, CATS, fiber optic cable, etc.), a wireless infrastructure (e.g., RF, cellular, microwave, satellite, Bluetooth, etc.), and/or other connection protocols. The devices 102(1)-(N), the pump(s) 106, the heat exchanger(s) 108, the valves 114(1)-(N), and the management system 118, and/or the sensor(s) 202 may have interfaces, controllers, modules, processor(s), etc. for communicating with one another.

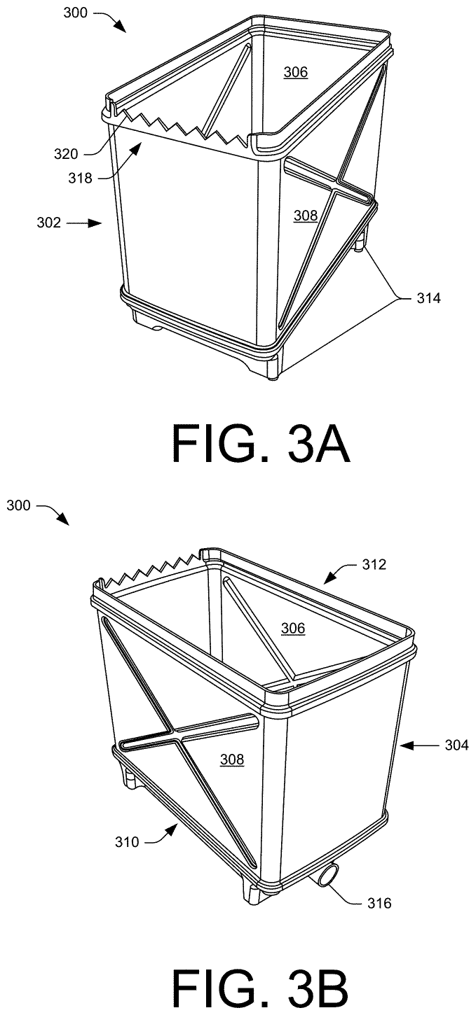

FIGS. 3A and 3B illustrate perspective views of a container 300, which may be similar to, or represent one of the containers 104(1)-(N). In some instances, the view shown in FIG. 3A may represent a front 302 of the container 300, whereas the view shown in FIG. 3B may represent a back 304 of the container 300.

Generally, the container 300 may include a rectangular shaped body with a cavity, or interior 306, configured to receive a device (as discussed above). For example, the container 300 may include sidewalls 308 that extend between a bottom 310 of the container 300 and a top 312 of the container 300. However, although shown as being a certain shape, the container 300 may be differently shaped (e.g., cylindrical, hexagonal, square, etc.). In such instances, the container 300 may include more than or less than four sidewalls.

The bottom 310 may include legs 314 that support the container 300 above a surface. For example, as discussed above in FIG. 1, the container 300 may be placed within a through. The legs 314 may support the bottom 310 of the container 300 above a surface of the container 300 to allow fluid to flow underneath (e.g., once the fluid exits the container 300 or other containers within the through).

The container 300 is shown including an inlet 316 that is disposed proximate to the bottom 310. The inlet 316 may fluidly couple to a line for receiving fluid. In some instances, the inlet 316 may be located at the back 304 of the container 300. The inlet 316 fluidly connects to the interior 306 such that the fluid may fill the interior 306 of the container 300 for cooling a device. Locating the inlet 316 proximate to the bottom 310 allows the fluid to enter the interior 306, pass around, over, through, etc. the device, and then exit. In some instances, and although not shown, a valve may be integrated within the container 300 for varying the flow or fluid, or the valve may be located along a line fluidly connected to the container 300. In any event, the valve may be a component of the container 300 or a separate component.

The top 312 of the container 300 is shown being opened to allow the fluid to exit the interior 306 (or more generally, the container 300). For example, as the fluid enters the container 300 and absorbs heat from a device, the fluid may exit the container 300 as new fluid is supplied into the container 300. The fluid may exit an outlet 318 of the container 300, at the front 302. In some instances, the outlet 318 may be located proximate to the top 312 and at the front 302. Additionally, or alternatively, the outlet 318 may be located along one or more sidewalls 308 of the container 300 and/or at the back 304.

The outlet 318 is shown as a series of serrations 320 (e.g., grooves, channels, etc.) that extend across the front 302. In some instances, the serrations 320 may be offset from the top 312 of the container 300, in a direction towards the bottom 310. In doing so, the fluid may not fill an entirety of the container 300 (or the interior 306), but may exit the outlet 318 prior to the doing so. This may avoid components of the devices coming into contact with the fluid (e.g., power cord, Ethernet connection, etc.). In some instances, the outlet 318 may represent a spillway in which the fluid cascades over before being collected by the through and routed to the heat exchanger.

In some instances, the interior 306 and/or the top 312 may include tabs, flanges, or other features that support the devices. For example, the interior 306 may include posts that offset the device from a bottom surface of the interior 306. This may allow the fluid to pass underneath the device once placed in the container 300 and/or ensure consistent heat transfer away from the device and/or a uniform flow of the fluid around the device and/or within the container 300. In some instances, the interior 306 of the container 300 may include a rack onto which the device rests (e.g., bottom).

In some instances, the container 300 may be manufactured from a plurality of materials, including, but not limited to plastic, metal, composites, and/or any combination thereof. Additionally, in some instances, the container 300 may be made of materials that are impermeable and/or weather-resistant. The container 300 may be manufactured using a plurality of process, such as injection molding, 3D printing, blow molding, bending, stamping, and so forth. Additionally, as discussed hereinabove, the container 300 may be sized to receive devices of different shapes and sizes. In such instances, the container 300 may be taller, wider, and/or longer than shown. Moreover, the container 300 may include indents, extrusions, bulges, etc. for accommodating features of the devices 102(1)-(N). In some instances, the container 300 may be tailored or manufactured based at least in part on the device configured to reside within the container 300. For example, a height of the container 300 may be dependent upon the device placed within the container 300.

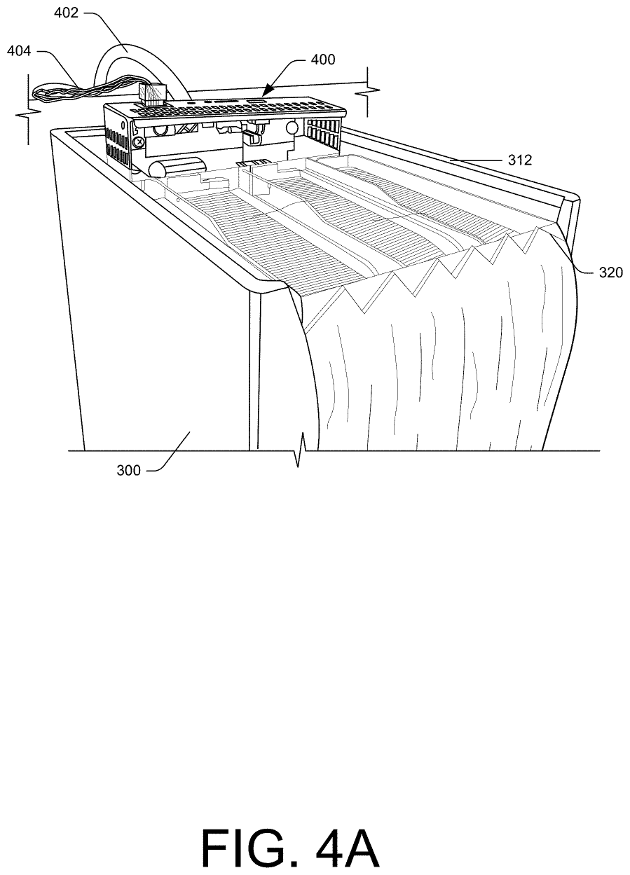

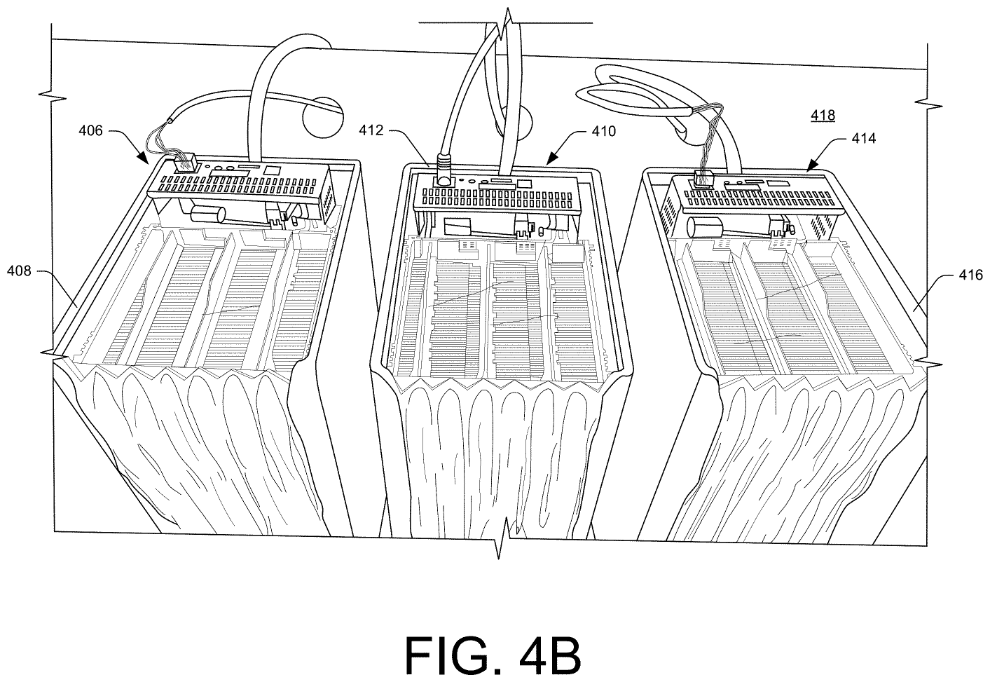

FIG. 4A illustrates a device 400 (e.g., among the devices 102(1)-(N)) disposed within the container 300. As shown, the device 400 may at least partially be disposed within the container 300 within the sidewalls 308. In doing so, when the container 300 is filled with fluid, the device 400 may be at least partially submerged within the fluid.

A portion of the device 400 is shown residing, or being disposed, above the top 312 of the container 300 and above the fluid. Here, the device 400 may couple to power and/or the management system 118 (or the network 204). For example, a first cable 402 is shown being coupled to the device 400 and may represent a power cord. A second cable 404 is shown being coupled to the device 400 and may represent an Ethernet cord. The device 400 may provide various information to the management system 118 via the second cable 404, such as an operating temperature of the device 400, a load on the device 400, and so forth.

The fluid is shown exiting the container 300 via the serrations 320, which may generally represent the outlet 318 of the container 300. For example, the fluid may flow over, through, or in between the serrations for exiting the container 300 and for collection within the trough 116. As discussed above, the serrations 320 (or the outlet 318) may be located vertically lower than the top such that the fluid exits the outlet 318 and not over other sides of the container 300. This may additionally prevent fluid from coming into contact with the first cable 402 and/or the second cable 404 (or ports into which the first cable 402 and the second cable 404 plug into). Moreover, although the second cable 404 is shown being coupled the device 400, the device 400 may wirelessly communicate with the management system 118 for providing information (e.g., temperature, load, etc.).

FIG. 4B illustrates devices disposed within containers. For example, a first device 406 may be disposed within a first container 408, a second device 410 may be disposed within a second container 412, and a third device 414 may be disposed within a third container 416. Additionally, each of the first device 406, the second device 410, and the third device 414 may include a portion that is disposed external to the first container 408, the second container 412, and the third container 416, respectively, for receiving power and/or other cables. Such portions may be disposed vertically above the fluid. The first container 408, the second container 412, and the third container 416 are showing being disposed in a basin 418, which may be similar to the trough 116. The basin 418 may collect fluid that exits first container 408, the second container 412, and the third container 416 for circulating to the heat exchanger(s) 108 for conditioning.

Although FIG. 4B illustrates that the first container 408, the second container 412, and the third container 416 each contain a separate device, in some instances, the first container 408, the second container 412, and/or the third container 416 may receive more than one device. Additionally, the first container 408, the second container 412, and the third container 416 are shown as being similar in size, shape, etc., the first container 408, the second container 412, and/or the third container 416 may include different shapes and sizes than shown, or in comparison to one another. Further, and as discussed in detail herein, each of the first container 408, the second container 412, and/or the third container 416 may fluidly couple to a valve that controls the amount of fluid provided to the first container 408, the second container 412, and the third container 416, respectively.

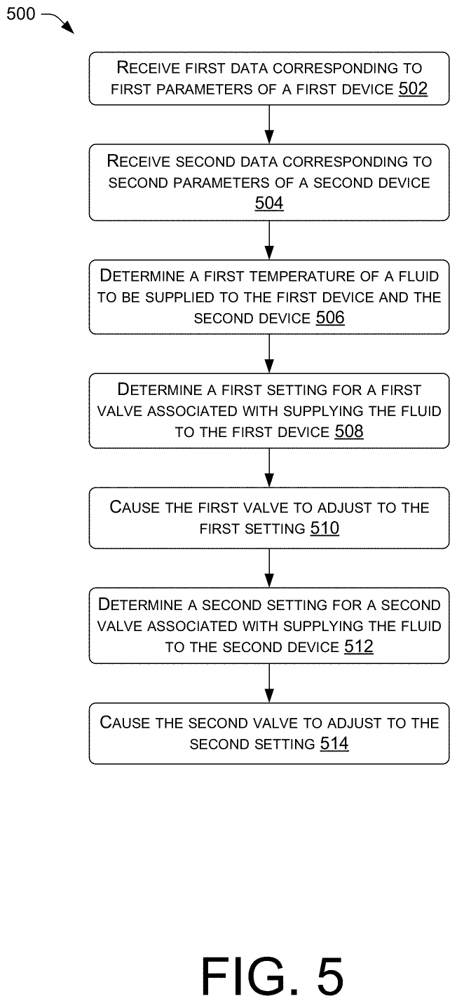

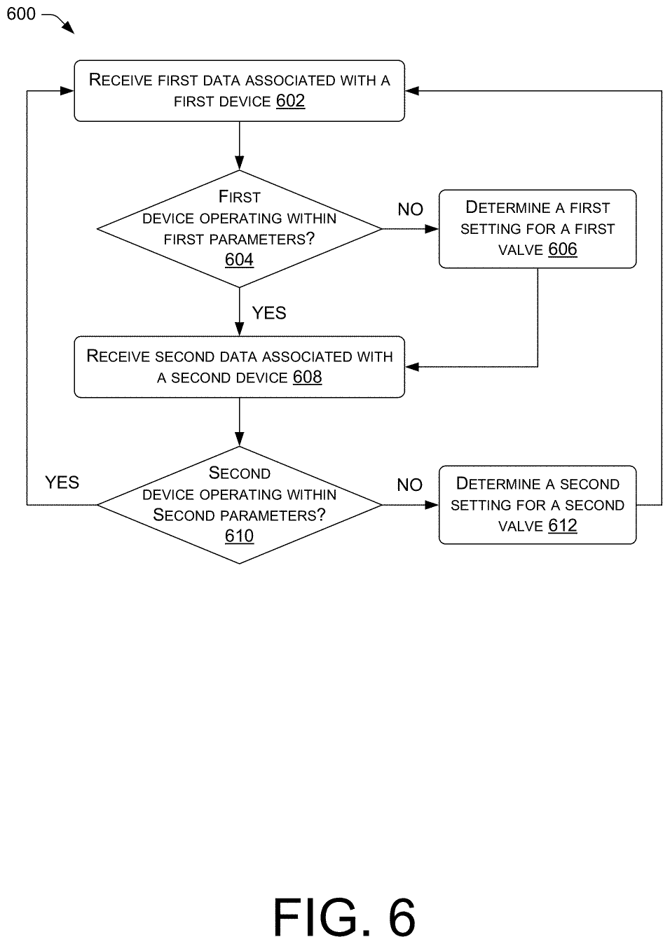

FIGS. 5 and 6 illustrate various processes for determining a flow rate of fluid supplied to one or more devices and/or adjusting the flow rate of fluid supplied to the one or more devices. The processes described herein are illustrated as collections of blocks in logical flow diagrams, which represent a sequence of operations, some or all of which may be implemented in hardware, software, or a combination thereof. In the context of software, the blocks may represent computer-executable instructions stored on one or more computer-readable media that, when executed by one or more processors, program the processors to perform the recited operations. Generally, computer-executable instructions include routines, programs, objects, components, data structures and the like that perform particular functions or implement particular data types. The order in which the blocks are described should not be construed as a limitation, unless specifically noted. Any number of the described blocks may be combined in any order and/or in parallel to implement the process, or alternative processes, and not all of the blocks need be executed. For discussion purposes, the processes are described with reference to the environments, architectures, devices, and systems described in the examples herein, such as, for example those described with respect to FIGS. 1-4, although the processes may be implemented in a wide variety of other environments, architectures, devices, and systems.

FIG. 5 illustrates an example process 500. At 502, the process 500 may include receiving first data corresponding to first parameters of a first device. For example, the management system 118 may receive, or otherwise determine, the first parameters of the first device (e.g., the operating parameters 128). In some instances, the first parameters may indicate a preferred operating temperature of the first device, a preferred operating load (e.g., capacity) of the first device, and so forth. In some instances, the first data may be stored in association with the first device (as the operating parameters 128) and/or in the device registry 126.

At 504, the process 500 may include receiving second data corresponding to second parameters of a second device. For example, the management system 118 may receive, or otherwise determine, the second parameters of the second device (e.g., the operating parameters 128). In some instances, the first parameters may indicate a preferred operating temperature of the second device, a preferred operating load (e.g., capacity) of the second device, and so forth. In some instances, the second data may be stored in association with the second device (as the operating parameters 128) and/or in the device registry 126.

At 506, the process 500 may include determining a first temperature of a fluid to be supplied to the first device and the second device. For example, the management system 118 may receive, from one or more sensor(s), a temperature of fluid that is supplied to containers in which the first device and the second device reside, respectively. In some instances, the sensor(s) (e.g., temperature sensor), may be placed in the containers, along lines that supply fluid to the containers, within pumps, heat exchangers, and so forth.

At 508, the process 500 may include determining a first setting for a first valve associated with supplying the fluid to the first device. For example, based at least in part on the first parameters, the management system 118, or components thereof, such as the adjustment component 134, may determine a setting for the first valve. In some instances, the setting of the first valve may correspond to how much the first valve is opened or closed. This, in effect, results in an adjustment to the flow rate of fluid supplied into the container in which the first device resides. In doing so, a flow rate of fluid supplied to the container may be adjusted such that the first device operates according to the first parameters. That is, if the first device has an optimal operating temperature, the first valve may be adjusted such that a particular heat transfer between the first device and the fluid is achieved that results in the first device operating at the optimal temperature. Opening the first valve may result in an increased flow rate of fluid to more quickly cool the first device, whereas closing the valve may result in a decreased flow rate to cool the first device more slowly.

At 510, the process 500 may cause the first valve to adjust to the first setting. For example, the adjustment component 134 may communicate with the first valve. In response, the first valve may open or close by a desired amount such that a particular flow rate of fluid is supplied to the container in which the first device resides.

At 512, the process 500 may include determining a second setting for a second valve associated with supplying the fluid to the second device. For example, based at least in part on the second parameters, the management system 118, or components thereof, such as the adjustment component 134, may determine a setting for the second valve. In some instances, the setting of the second valve may correspond to how much the second valve is opened or closed. This, in effect, results in an adjustment to the flow rate of fluid supplied into the container in which the second device resides. In doing so, a flow rate of fluid supplied to the container may be adjusted such that the second device operates according to the second parameters.

At 514, the process 500 may cause the second valve to adjust to the second setting. For example, the adjustment component 134 may communicate with the second valve. In response, the second valve may open or close by a desired amount such that a particular flow rate of fluid is supplied to the container in which the second device resides.

Although the process 500 describes determining the settings for valves associated with two containers, the process 500 may determine the settings for valves for a plurality of devices within a given environment.

FIG. 6 illustrates an example process 600 for adjusting a flow rate of fluid supplied to containers. At 602, the process 600 may include receiving first data associated with a first device. In some instances, the first data may include an operating temperature of the first device, a temperature of fluid entering or exiting a container in which the first device resides, a load of the first device, an amount of power supplied to the first device or consumed by the first device, and so forth. In some instances, the first data may be received responsive to an event (e.g., first device powering up, first device powering down, a temperature change in the fluid, load of the first device increasing or decreasing, or according to predetermined schedules (e.g., every second, every minute, etc.).

At 604, the process 600 may include determining whether the first device is operating within first parameters associated with the first device. For example, if the first device includes an optimal operating temperature of 100 degrees Fahrenheit, and the first data indicates that the temperature of the first device is 110 Fahrenheit, the process 600 may determine that the first device is not operating within the first parameters. In some instances, this may include determining whether the first device is operating outside a range, threshold, or window associated with the first parameters. For example, an operating temperature of 105 degrees Fahrenheit may be within range of the optimal operating temperature, and in such instances, the first device may be operating within the first parameters. As noted above, the optimal operating temperatures may be associated with the first device performing a certain number of hashes per second. If at 604, the process 600 determines that the first device is not operating within the first parameters, the process 600 may follow the “NO” route and proceed to 606.

At 606, the process 600 may include determining a first setting for a first valve that supplies fluid to a container in which the first device resides. For example, if the operating temperature of the first device is greater than the optimal operating temperature (or more than a threshold amount), the process 600 may determine to open the first valve to increase a flow rate of fluid supplied to the container. In effect, this may increase the amount of fluid that enters the container, and thus, the first device may be cooled. The amount by which the first valve is opened may be dependent upon the optimal operating temperature of the first device. For example, the first valve may be opened by a given amount such that the first device operates at the optimal temperature. From 606, the process 600 may proceed to 608. Additionally, the process 600 may proceed to 608 following the “YES” route from 604.

At 608, the process 600 may include receiving second data associated with a second device. In some instances, the second data may include an operating temperature of the second device, a temperature of fluid entering or exiting a container in which the second device resides, a load of the second device, an amount of power supplied to the second device or consumed by the second device, and so forth. In some instances, the second data may be received responsive to an event (e.g., second device powering up, second device powering down, temperature change in the fluid, load of the second device increasing or decreasing) or according to predetermined schedules (e.g., every second, every minute, etc.).

At 610, the process 600 may include determining whether the second device is operating within second parameters associated with the second device. For example, if the second device includes a maximum operating load (e.g., usage), and the second data indicates that the operating load of the second device is less than the maximum operating load (e.g., 90 percent), the process 600 may determine that the second device is not operating within the second parameters. In some instances, the second device may not be operating at its maximum load given a temperature of the second device. In some instances, determining whether the second device is operating within the second parameters may include determining whether the second device is operating outside a range, threshold, or window associated with the second parameters.

If at 610, the process 600 determines that the second device is operating within the second parameters, the process 600 may follow the “YES” route and proceed to 602. That is, the process 600 may continue to receive data associated with the first device and/or the second device for use in determining adjustments to make to the first valve and/or the second valve, respectively. Alternatively, if at 610, the process 600 determines that the second device is not operating within the second parameters, the process 600 may follow the “NO” route and proceed to 612.

At 612, the process 600 may include determining a second setting for a second valve that supplies fluid to a container in which the second device resides. For example, if the load of the second device is less than the maximum operating load (or more than a threshold amount), the process 600 may determine to open the second valve to increase a flow rate of fluid supplied to the container. In effect, this may increase the amount of fluid that enters the container, and thus, the second device may be cooled. The amount by which the second valve is opened may be dependent upon the optimal operating temperature of the second device. For example, the first valve may be opened by a given amount such that the second device operates at the optimal temperature.

From 612, the process 600 may loop to 602 whereby the process 600 may continue to receive data associated with the first device and/or the second device for use in determining adjustments.

Although the process 600 describes determining settings for valves, the process 600 may determine settings for other components. For example, the process 600 may determine to increase a pumping speed (or power) of the pump(s) 106 to increase the flow rate of fluid. Additionally, or alternatively, the process 600 may determine to adjust settings of the heat exchanger(s) 108 to increase or decrease conditioning (e.g., based on ambient temperatures, weather, etc.).

Moreover, although the process 600 describes receiving data from the devices themselves for use in adjusting the valves, other sensor(s) may be used for modulating the flow of the fluid. For example, a thermometer may measure an output temperature of fluid exiting the container. If the temperature is below a certain threshold (e.g., too cold), the flow of the fluid into the container may be reduced. The valves may also be adjusted as devices are commissioned and/or decommissioned. As an additional example, the process 600 may receive information associated with the number of hashes being performed by the devices per second. If the number of hashes is less than an optimal amount for the devices, the flow rate into the container may be increased (e.g., too hot) or decreased (e.g., too cold). As such, the flow rate may be optimized according to the hash rates of the devices. In any of these events, the process 600 efficiently utilize resources for cooling the devices and reducing waste.

While the foregoing invention is described with respect to the specific examples, it is to be understood that the scope of the invention is not limited to these specific examples. Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Although the application describes embodiments having specific structural features and/or methodological acts, it is to be understood that the claims are not necessarily limited to the specific features or acts described. Rather, the specific features and acts are merely illustrative some embodiments that fall within the scope of the claims of the application.

What is claimed is:

1. An apparatus comprising:
an enclosed bottom;
an open end opposite the enclosed bottom;
a first sidewall extending from the enclosed bottom to the open end;
a second sidewall extending from the enclosed bottom to the open end, the second sidewall being opposite the first sidewall;
a back extending from the enclosed bottom to the open end, the back being coupled to the first sidewall and the second sidewall;
a front extending from the enclosed bottom to the open end, the front being coupled to the first sidewall and the second sidewall;
an interior cavity defined between the first sidewall, the second sidewall, the back, and the front;
an inlet disposed on the back and fluidly connected to the interior cavity; and
an outlet disposed on the front and fluidly connected to the interior cavity, the outlet being spaced apart from the open end in a direction towards the enclosed bottom.

2. The apparatus of claim 1, wherein:
the inlet is located more proximate to the enclosed bottom than the open end; and
the outlet is located more proximate to the open end than the enclosed bottom.

3. The apparatus of claim 1, further comprising one or more legs extending from the enclosed bottom, exterior to the interior cavity.

4. The apparatus of claim 1, further comprising one or more tabs extending from the enclosed bottom, within the interior cavity.

5. The apparatus of claim 4, wherein:
the interior cavity is configured to receive a computing device; and
the one or more tabs engage an end of the computing device such that the end of the computing device is offset from the enclosed bottom.

6. The apparatus of claim 1, wherein the outlet comprises:
one or more serrations extending across the front, between the first sidewall and the second sidewall; and
the one or more serrations include a trough that is spaced apart from the open end, in the direction towards the enclosed bottom.

7. The apparatus of claim 1, wherein the apparatus is substantially rectangular-shaped.

8. A container configured to receive a computing device, comprising:
a bottom;
an open top opposite the bottom;
a first side;
a second side opposite the first side;
a third side;
a fourth side opposite the third side;
an interior cavity defined at least in part by the bottom, the end top, the first side, the second side, the third side, and the fourth side, the interior cavity being configured to receive at least a portion of the computing device, the interior cavity being configured to hold a fluid therein;
an inlet fluidly connected to the interior cavity;
an outlet fluidly connected to the interior cavity, the outlet including grooves, individual grooves of the grooves having:
adjacent peaks, and
a trough disposed between the adjacent peaks, the trough being spaced apart from the open top in a direction towards the bottom.

9. The container of claim 8, further comprising one or more feet extending from the bottom, exterior to the interior cavity.

10. The container of claim 8, further comprising one or more tabs extending from the bottom, within the interior cavity.

11. The container of claim 8, wherein a size of the container is based at least in part on the computing device.

12. The container of claim 8, wherein:
the inlet is disposed on the first side; and
the outlet is disposed on the second side.

13. The container of claim 12, wherein the grooves extend across the second side, in a second direction that is transverse to the direction.

14. The container of claim 8, wherein:
the inlet is located more proximate to the bottom than the open top; and
the outlet is located more proximate to the open top than the bottom.

15. An apparatus comprising:
a substantially-rectangular body defining an interior cavity, the interior cavity being configured to hold a fluid;
an inlet fluidly connected to the interior cavity, the inlet being configured to supply the fluid to the interior cavity; and
an outlet fluidly connected to the interior cavity, the outlet being configured to discharge the fluid from the interior cavity, the outlet including a plurality of serrations.

16. The apparatus of claim 15, wherein:
the inlet is located more proximate a first end of the substantially-rectangular body than a second end of the substantially-rectangular body; and
the outlet is located more proximate the second end of the substantially-rectangular body than the first end of the substantially-rectangular body.

17. The apparatus of claim 16, wherein individual serrations of the plurality of serrations have:
a top, and
a bottom that is spaced apart from the second end, in a direction towards the first end.

18. The apparatus of claim 16, wherein:
the substantially-rectangular body includes a bottom, a first sidewall, a second sidewall, a third sidewall, and a fourth sidewall that define the interior cavity;
the first sidewall is coupled to the second sidewall and the fourth sidewall; and
the plurality of serrations extend across the first sidewall, between the second sidewall and fourth sidewall.

19. The apparatus of claim 18, wherein the outlet is located on the third sidewall, the third sidewall being opposite the first sidewall.

20. The apparatus of claim 15, further comprising at least one of:
one or more feet extending the substantially-rectangular body, exterior to the interior cavity; or
one or more tabs extending from the substantially-rectangular body, within the interior cavity.
